(19) United States
(12) Patent Application Publication
(10) Pub. No.: US 2014/0290716 A1
(43) Pub. Date: Oct. 2, 2014

(54) PHOTOVOLTAIC MODULE MOUNTING ASSEMBLY

(71) Applicant: Unirac, Inc., Albuquerque, NM (US)

(72) Inventor: Charles William STUBBS, Tijeras, NM (US)

(73) Assignee: Unirac, Inc., Albuquerque, NM (US)

(21) Appl. No.: 14/225,061

(22) Filed: Mar. 25, 2014

Related U.S. Application Data
(60) Provisional application No. 61/806,722, filed on Mar. 29, 2013.

(51) Int. Cl. H01L 31/042

(52) U.S. Cl. CPC H01L 31/0422; H02S 20/00
USPC 136/251; 248/201; 248/542

(57) ABSTRACT

A photovoltaic module mounting assembly is disclosed. The assembly includes a bearing cradle assembly, a first mounting bracket, and a second mounting bracket. The bearing cradle assembly is attached to the first and second mounting brackets.

This application claims the benefit of U.S. Provisional Application No. 61/806,722, filed Mar. 29, 2013, the disclosure of which is expressly incorporated by reference herein.

### BACKGROUND OF THE INVENTION

The solar industry is growing world-wide and, as a result, more-efficient structures are desirable for a photovoltaic module mounting assembly. Whereas many different structures are known, there is a desire to improve the efficiency of such structures.

Therefore, there is a need for an improved photovoltaic module mounting assembly.

### BRIEF DESCRIPTION OF THE DRAWINGS

FIGS. 1A1, 1A2, 1B1, 1B2, 1C1, and 1C2 are perspective views of alternative embodiments for a bearing cradle assembly, a first bracket, a second bracket, and a mounting pile in accordance with the principles of the present invention;

FIG. 2A is an exploded perspective view of the embodiment of FIGS. 1A1 and 1A2;

FIG. 2B is a top view of the embodiment of FIG. 2A;

FIG. 2C is a cross-sectional view of the embodiment of FIG. 2A as taken along line 2C-2C of FIG. 2B;

FIG. 2D is an assembled perspective view of the embodiment of FIG. 2A;

FIG. 3A is an exploded perspective view of the embodiment of FIGS. 1B1 and 1B2;

FIG. 3B is an assembled perspective view of the embodiment of FIG. 3A;

FIG. 4A is an exploded perspective view of the embodiment of FIGS. 1C1 and 1C2;

FIG. 4B is an assembled perspective view of the embodiment of FIG. 4A;

FIG. 5 is a perspective view illustrating the positioning of the indicators, apertures, and shot pins in a mounting bracket of an assembly in accordance with the principles of the present invention;

FIG. 6 is a perspective view illustrating the positioning of the indicators, apertures, and shot pins in the mounting bracket of the opposing side of the assembly of FIG. 5 in accordance with the principles of the present invention;

FIG. 7 is a perspective view illustrating the positioning of the indicators, apertures, and shot pins in a mounting bracket of an assembly in accordance with the principles of the present invention;

FIG. 8 is a perspective view illustrating the positioning of the indicators, apertures, and shot pins in the mounting bracket of the opposing side of the assembly of FIG. 7 in accordance with the principles of the present invention;

FIG. 9 further illustrates the bearing cradle assembly and positioning of the indicators, apertures, and shot pins in accordance with the principles of the present invention;

FIG. 10 is a top view of an embodiment of the U-shaped mounting base of FIG. 9 in accordance with the principles of the present invention;

FIGS. 11A and 11B illustrate an embodiment of a top chord assembly in accordance with the principles of the present invention;

FIGS. 12A-12J illustrate an assembled mounting assembly in accordance with the principles of the present invention;

FIG. 13 illustrates an alternative embodiment of a top chord assembly in accordance with the principles of the present invention;

FIG. 14 illustrates a further alternative embodiment of a top chord assembly in accordance with the principles of the present invention;

FIG. 15 further illustrates the top chord assembly of FIG. 14; and

FIG. 16 illustrates an assembled mounting assembly with the top chord assembly of FIGS. 14 and 15.

### DETAILED DESCRIPTION OF THE DRAWINGS

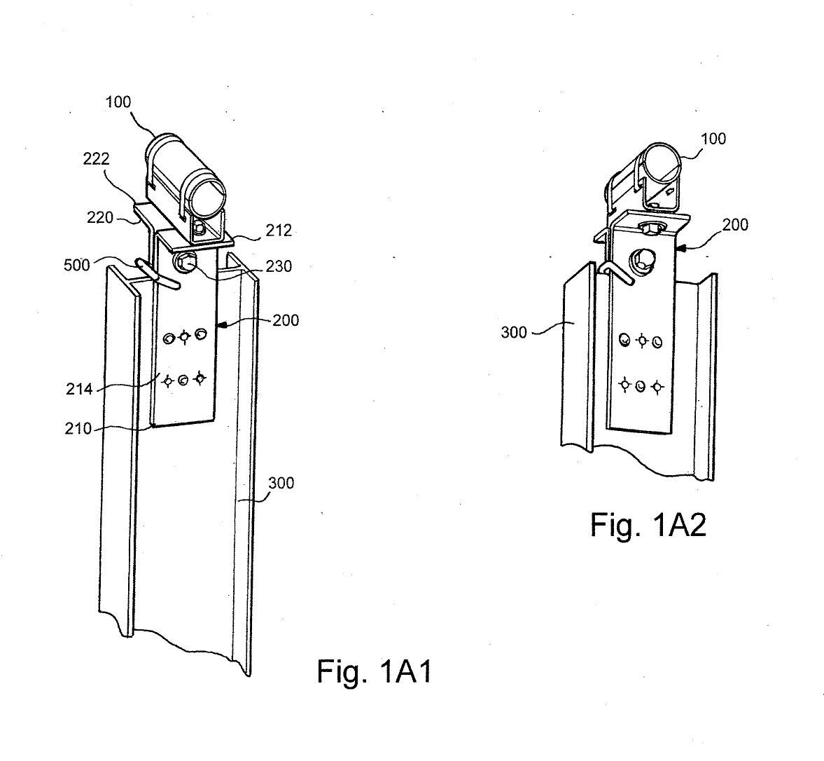

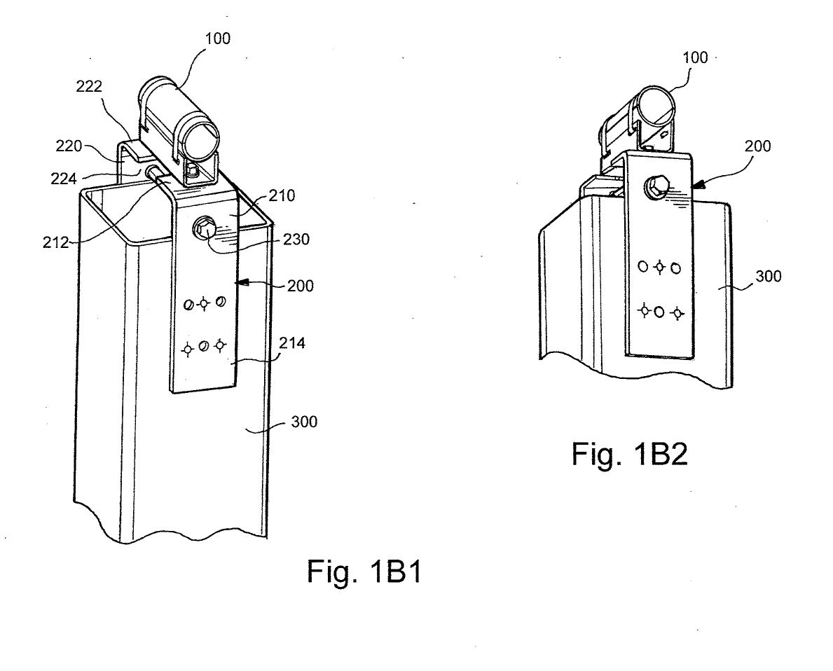

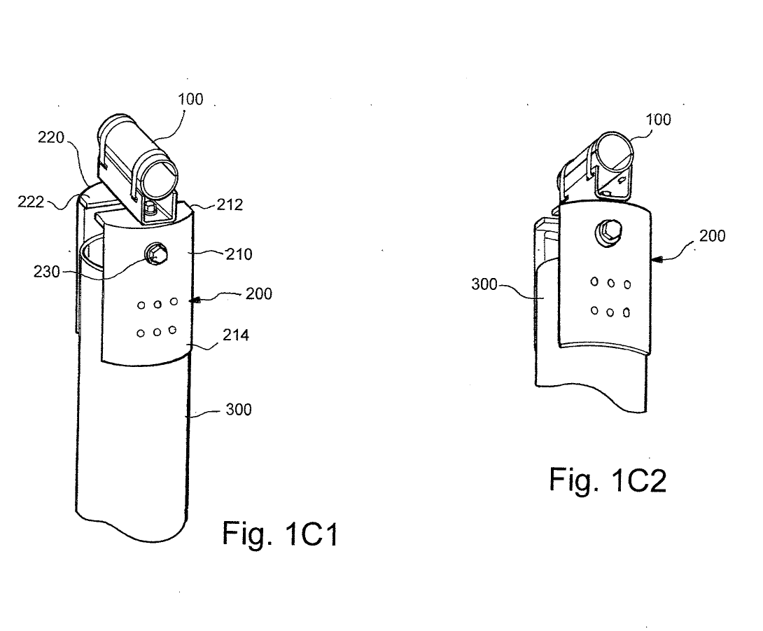

FIGS. 1A1, 1A2, 1B1, 1B2, 1C1, and 1C2 illustrate alternative embodiments for a bearing cradle assembly 100, a bracket assembly 200 including a first mounting bracket 210 and a second mounting bracket 220, and a mounting pile 300 in accordance with the principles of the present invention. The first mounting bracket 210 is connected to the second mounting bracket 220 and the bearing cradle assembly 100 is attached to the first mounting bracket 210 and the second mounting bracket 220. The mounting brackets 210, 212 are attached to the mounting pile 300.

The first mounting bracket 210 and the second mounting bracket 220 are both L-shaped.

In the embodiment of FIGS. 1A1 and 1A2, an extending portion 212 of the first L-shaped mounting bracket 210 is disposed in an opposite direction from an extending portion 222 of the second L-shaped mounting bracket 220.

In the embodiments of FIGS. 1B1, 1B2 and 1C1, 1C2, the extending portion 212 of the first L-shaped mounting bracket 210 is disposed toward the extending portion 222 of the second L-shaped mounting bracket 220.

In the embodiments of FIGS. 1A1, 1A2, 1B1, 1B2, 1C1, and 1C2, the first mounting bracket 210 is connected to the second mounting bracket 220 by a connecting member 230, and in the illustrated embodiment the connecting member 230 is a bolt. The bolt 230 is disposed through an elongated portion 214 of the first L-shaped mounting bracket 210 and an elongated portion 224 of the second L-shaped mounting bracket 220.

As can be further seen in FIGS. 1A1, 1A2, 1B1, 1B2, 1C1, and 1C2, and as mentioned above, the mounting assembly further includes a mounting pile 300 that is disposed between the first mounting bracket 210 and the second mounting bracket 220. In the illustrated embodiments, the mounting pile 300 has a wide flange shape in FIGS. 1A1 and 1A2, a square shape in FIGS. 1B1 and 1B2, and a round shape in FIGS. 1C1 and 1C2. As can be seen, the wide flange shape of FIGS. 1A1 and 1A2 generally has a configuration similar to an “H”, and thus, can be an “I” beam. The configuration of the mounting brackets 210, 220 is complementary to the configuration of the mounting pile, e.g., a flat bracket and a flat mounting pile surface and a rounded bracket and a rounded mounting pile surface. The end of the mounting pile that is opposite from the end on which the mounting brackets 210, 220 and bearing cradle assembly 100 are disposed is mounted on the ground.

Thus, as will be further explained, the bearing cradle assembly 100, bracket assembly 200, and mounting pile 300 are used in the mounting of a photovoltaic (PV) module on a surface, such as the ground. The other components of the mounting assembly will be described later in this specification.

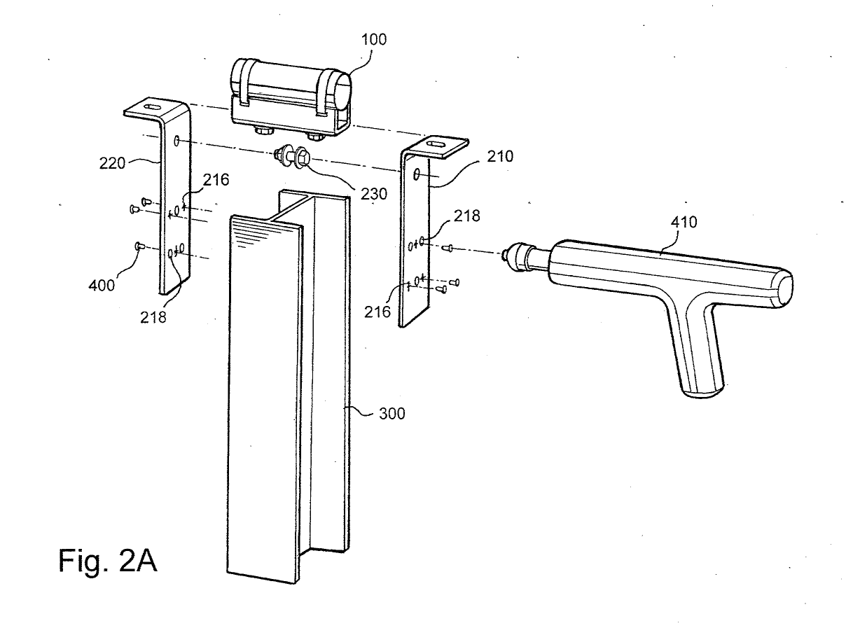

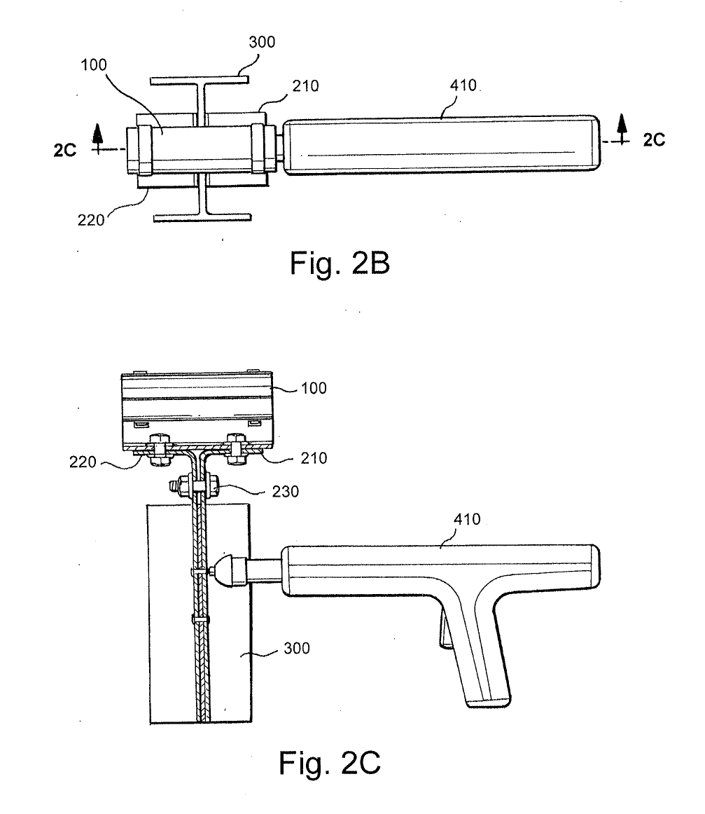

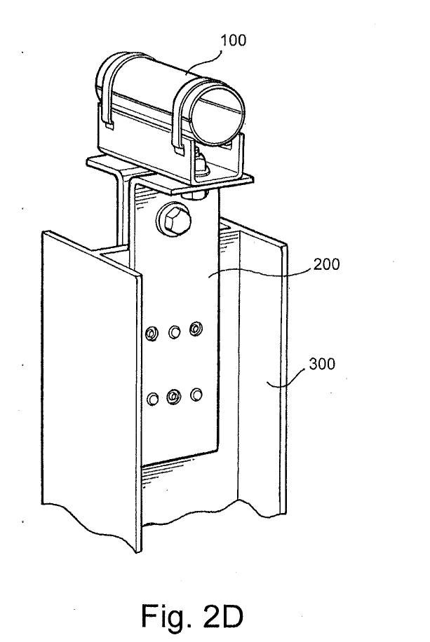

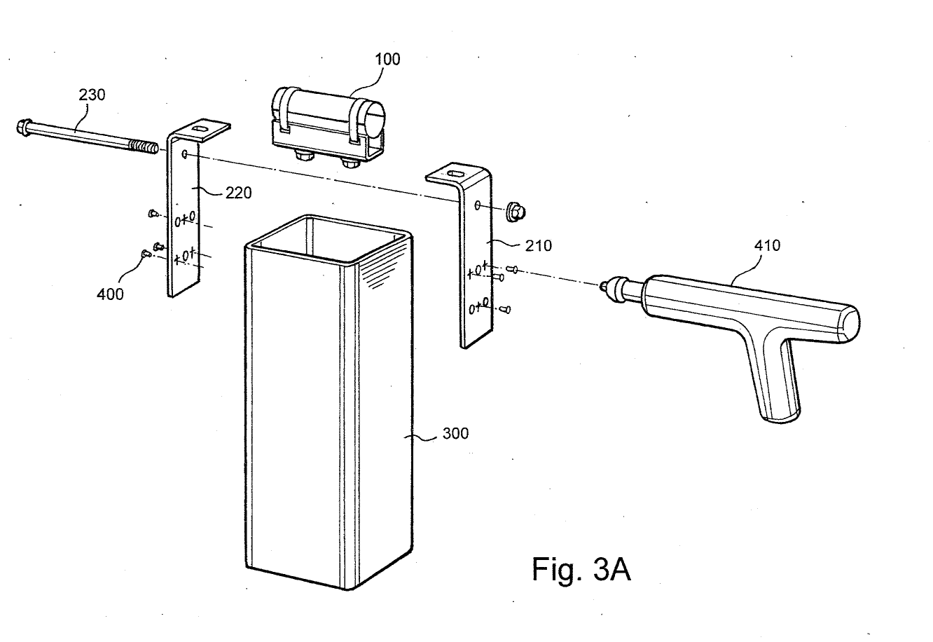

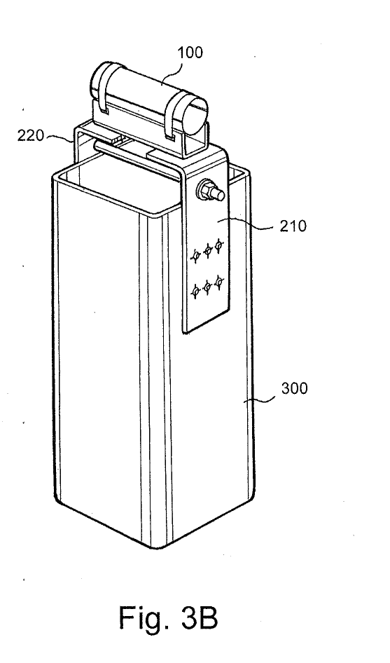

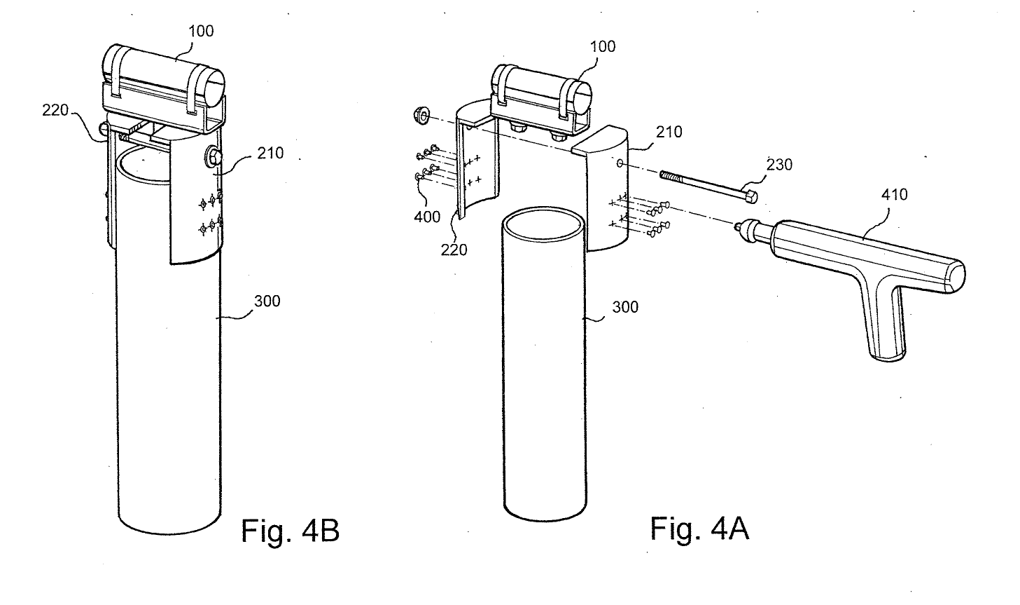

FIGS. 2A-2D further illustrate the embodiment of FIGS. 1A1 and 1A2 of the wide flange shape pile 300 and associated bearing cradle assembly 100, brackets 210, 220, and bolt 230; FIGS. 3A-3B further illustrate the embodiment of FIGS. 1B1 and 1B2 of the square shape pile 300 and associated bearing cradle assembly 100, brackets 210, 220, and bolt 230; and FIGS. 4A-4B further illustrate the embodiment of FIGS. 1C1 and 1C2 of the round shape pile 300 and associated bearing cradle assembly 100, brackets 210, 220, and bolt 230.

Particularly in the embodiment of FIGS. 1A1, 1A2, and 2A-2D, each of the first mounting bracket 210 and the second mounting bracket 220 has a plurality of indicators 216 and a plurality of apertures 218. The indicators may be of any form or structure. As such, for example, they may be in the form of cross-hairs embossed on the surface of the mounting brackets.

When the first 210 and second 220 mounting brackets are connected, the indicators 216 of the first mounting bracket 210 are disposed opposite from the apertures 218 of the second mounting bracket 220 and, likewise, the apertures 218 of the first mounting bracket 210 are disposed opposite from the indicators 216 of the second mounting bracket 220.

This is desirable since, as will be discussed further, when a shot pin 400 is shot into the bracket and mounting pile to further attach the mounting bracket to the mounting pile, the shot pin is most-effective if the shot pin only penetrates two structures, i.e., the mounting bracket and the mounting pile. If the shot pin was to engage a third structure, i.e., the opposing mounting bracket, the shot pin would push the opposing mounting bracket away from the mounting pile and mounting bracket. Thus, by providing an aperture in the opposing mounting bracket, the shot pin 400, for example, penetrates the mounting bracket 210 and mounting pile 300, but, does not engage the mounting bracket 220 on the other side of the mounting pile. The shot pin 400 is received in the corresponding aperture of the mounting bracket 220.

As discussed above, the indicators of one mounting bracket are aligned with the apertures of the opposing mounting bracket when the mounting brackets are secured onto the mounting pile, before the shot pins further secure the mounting brackets to the mounting pile. With this alignment, when the shot pin is fired at the position of the indicator on one mounting bracket, the shot pin is then received within the aligned aperture of the opposing mounting bracket.

A further benefit of the use of the aligned indicators and apertures is that a shot pin fired into one of the brackets at a respective indicator will not be located at a same position as a shot pin fired into the opposing bracket at a respective indicator. The indicators on the opposing brackets are not aligned with each other. Rather, as discussed above, they are aligned with respective apertures. Therefore, the shot pins fired in opposing brackets cannot interfere with each other since they are not co-located.

The shot pins are shot into the mounting brackets and mounting pile by a nail gun 410, as shown in the Figures. The nail gun can be explosive-powered, e.g. powder actuated or gas actuated, pneumatically powered, or powered in other ways. The present invention is not limited to using any particular type of mechanism for shooting the shot pins into the mounting brackets and mounting pile.

Thus, in a method for attaching the bearing cradle assembly 100 to the mounting pile 300, the mounting brackets 210, 220 are secured to the web of the mounting pile 300, before the firing of the shot pins 400, by use of the bolt 230 and a C-clamp 500, as illustrated in FIGS. 1A1 and 1A2. Thus, the bolt 230 secures the mounting brackets together at a top end of the brackets and the C-clamp 500 secures the mounting brackets together, and to the mounting pile 300, at a lower position on the mounting brackets. The bearing cradle assembly is bolted to the mounting brackets. Then, the shot pins 400 are fired into the mounting brackets and mounting pile to further secure the mounting brackets to the mounting pile, and thus, the bearing cradle assembly to the mounting pile.

Of course, the present invention is also not limited to only using shot pins to connect the mounting brackets to the mounting pile. Other connection hardware, e.g., bolts, can be used as well.

In the embodiments of FIGS. 1B1, 1B2, 3A-3B and FIGS. 1C1, 1C2, 4A-4B, the mounting brackets are separated from each other by a greater distance than in the embodiment of FIGS. 1A1, 1A2, 2A-2D by the square-shaped mounting pile and round-shaped mounting pile, respectively. Therefore, the shot pins cannot be fired into the opposing mounting bracket, and as such, the use of the indicators and apertures is not necessary, but can still be utilized.

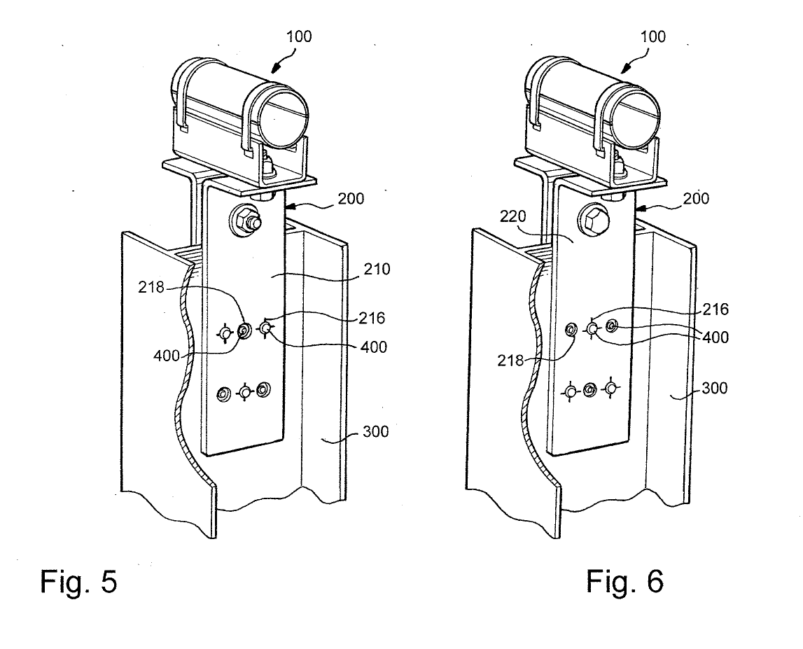

FIGS. 5-8 further illustrate the indicators 216, the apertures 218, and the shot pins 400. FIG. 5 is a perspective view illustrating the positioning of the indicators 216, apertures 218, and shot pins 400 in the mounting bracket 210 of an assembly in accordance with the principles of the present invention. FIG. 6 is a perspective view illustrating the positioning of the indicators 216, apertures 218, and shot pins 400 in the mounting bracket 220 of the opposing side of the assembly of FIG. 5. As can be seen, the indicators 216 of mounting bracket 210 are aligned with the apertures 218 of the opposing mounting bracket 220 when the mounting brackets 210, 220 are secured onto the mounting pile 300. With this alignment, when the shot pin 400 is fired at the position of the indicator on one mounting bracket, the shot pin is then received within the aligned aperture of the opposing mounting bracket.

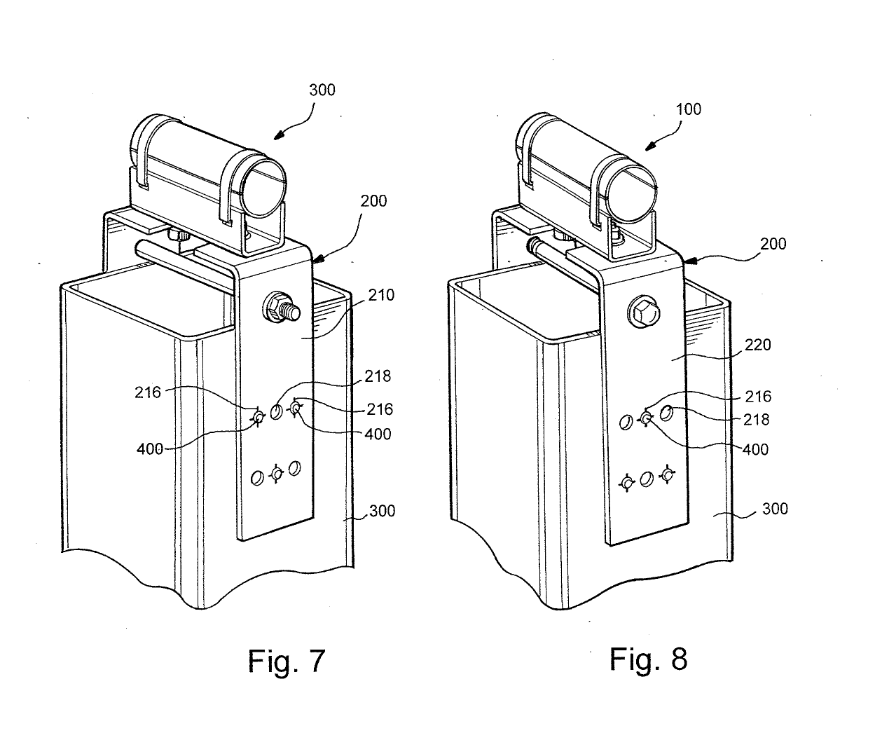

FIG. 7 is a perspective view illustrating the positioning of the indicators 216, apertures 218, and shot pins 400 in the mounting bracket 210 of another assembly in accordance with the principles of the present invention. In this embodiment, the mounting pile is the square shape pile. FIG. 8 is a perspective view illustrating the positioning of the indicators 216, apertures 218, and shot pins 400 in the mounting bracket 220 of the opposing side of the assembly of FIG. 7. Thus, as can be seen, the shot pins cannot be fired into the opposing mounting bracket, and as such, the use of the indicators and apertures is not necessary, but can still be utilized.

Therefore, as discussed above, the mounting pile 300 is disposed between the first mounting bracket 210 and the second mounting bracket 220. Each of the first and second mounting brackets, in an embodiment, have a plurality of indicators 216 and a plurality of apertures 218. An indicator 216 of the first mounting bracket 210 is disposed opposite from an aperture 218 of the second mounting bracket 220 and an aperture 218 of the first mounting bracket 210 is disposed opposite from an indicator 216 of the second mounting bracket 220. A first shot pin 400 is disposed through the indicator 216 of the first mounting bracket 210, through the mounting pile 300, and in the corresponding, aligned aperture 218 of the second mounting bracket 220. A second shot pin 400 is disposed through an indicator 216 of the second mounting bracket 220, through the mounting pile 300, and in the corresponding, aligned aperture 218 of the first mounting bracket 210. Similarly, additional shot pins are used with other aligned indicators and apertures of the two mounting brackets.

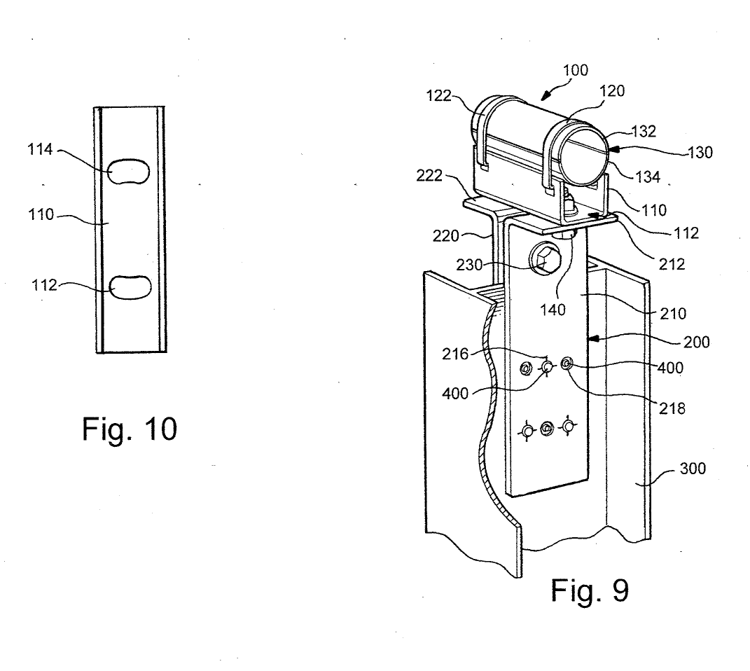

Further with respect to the present invention, particularly with reference to FIG. 9, however as can also be seen in other Figures, the bearing cradle assembly 100 includes a U-shaped mounting base 110, a first mounting member 120 and a second mounting member 122, and a cylindrical bearing cap 130. The cylindrical bearing cap 130 includes a first half-cylindrical bearing cap member 132 and a second half-cylindrical bearing cap member 134. The cylindrical bearing cap 130 is secured on the U-shaped mounting base 110 by the first and second mounting members 120, 122. Of course, two mounting members 120, 122 are not required. A single mounting member could be used to secure the cylindrical bearing cap 130 on the U-shaped mounting base 110.

As can be seen in FIG. 10, the U-shaped mounting base 110 includes a first crescent-shaped slot 112 and a second crescent-shaped slot 114. The first crescent-shaped slot 112 is aligned with a slot in the extending portion 212 of the first L-shaped mounting bracket 210 and the second crescent-shaped slot 114 is aligned with a slot in the extending portion 222 of the second L-shaped mounting bracket 220, as shown, for example, in FIG. 2A.

As can also be seen in FIG. 9, a first bolt 140 extends through the first crescent-shaped slot 112 and the slot in the extending portion 212 of the first L-shaped mounting bracket 210. Similarly, a second bolt extends through the second crescent-shaped slot 114 and the slot in the extending portion 222 of the second L-shaped mounting bracket 220.

Through the use of the crescent-shaped slots 112, 114, the positioning of the bearing cradle assembly 100 with respect to the bracket assembly 200 can be adjusted, e.g., laterally and in twist, via positioning of the bolts in the slots, which bolts connect the bearing cradle assembly 100 to the bracket assembly 200.

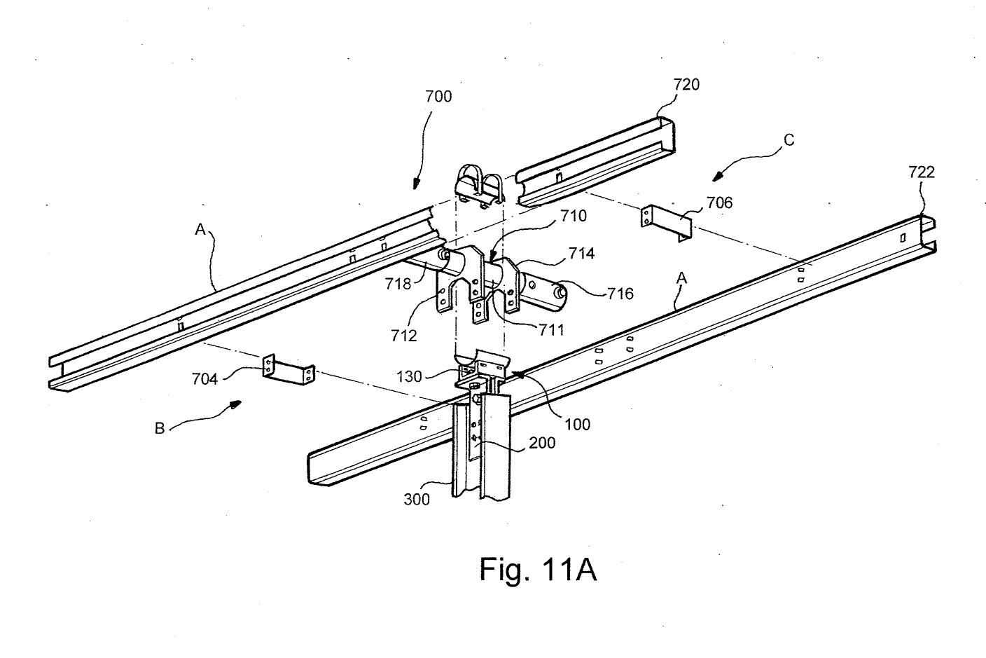

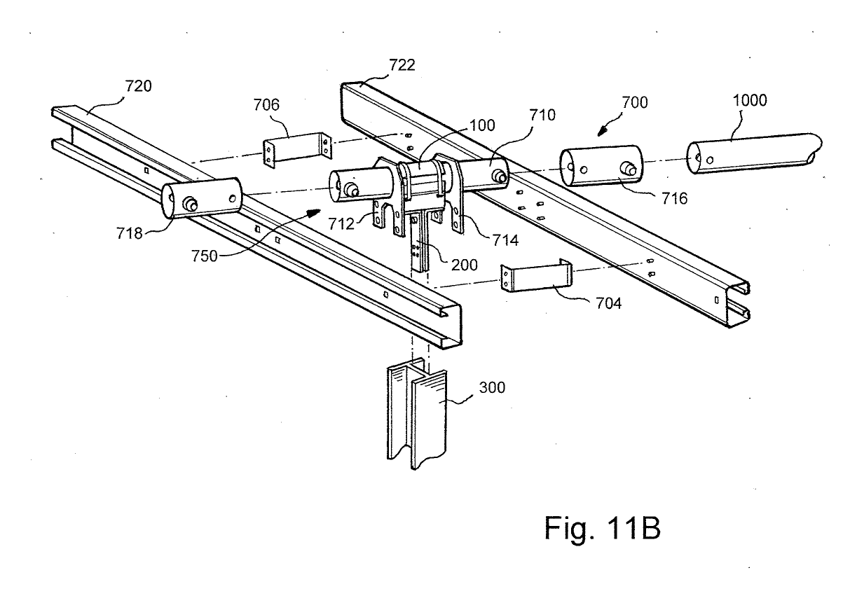

FIGS. 11A and 11B illustrate a top chord assembly 700 in accordance an embodiment of the present invention. In this embodiment, as can be seen in FIGS. 11A and 11B, the top chord assembly 700 includes a bearing stud 710. A cylindrical bearing 711 is disposed on the bearing stud 710. The cylindrical bearing 711 is disposed around the bearing stud 710 and may be in the form of a sleeve fitted around the bearing stud. The cylindrical bearing 711 may be formed of any material(s) that provides for rotational movement of the bearing stud 710 within the cylindrical bearing cap 130, e.g., Teflon®, epoxy resin, etc., and thus, within the bearing cradle assembly 100.

As will be further explained, the bearing stud 710 is rotatably disposed within the bearing cradle assembly 100. The bearing stud 710, bearing 711, and bearing cradle assembly 100 comprise a bearing assembly 750.

The bearing stud 710 is connected to a first top chord 720 and a second top chord 722 of the top chord assembly 700, where the first top chord 720 is adjacent to, and parallel to, the second top chord 722.

The bearing stud 710 is rigidly connected to the first and second top chords 720, 722 by a first top chord mounting bracket 712 and a second top chord mounting bracket 714 (yokes). The first top chord mounting bracket 712 is rigidly connected to the bearing stud 710 and the first top chord 720 and the second top chord mounting bracket 714 is rigidly connected to the bearing stud 710 and the second top chord 722. The mounting brackets 712 and 714 may be rigidly connected to the bearing stud 710, and the respective top chords, by any known means, e.g., connecting hardware, integral forming, etc.

A first end mounting bracket 704 is disposed between the first top chord 720 and the second top chord 722 at a first end B of the first and second top chords. The first end mounting bracket 704 connects the first top chord 720 to the second top chord 722 at the first end B.

A second end mounting bracket 706 is disposed between the first top chord 720 and the second top chord 722 at a second end C of the first and second top chords. The second end mounting bracket 706 connects the first top chord 720 to the second top chord 722 at the second end C.

Thus, as can be understood, the bearing stud 710 and the first and second top chords 720, 722 comprise a rigid top chord assembly 700 though use of the first and second top chord mounting brackets 712, 714 and the first and second end mounting brackets 704, 706. This rigid structure, and thus the top chords 720, 722, is rotatable around a center longitudinal axis of the bearing stud 710 through rotation of the bearing stud 710 around this axis in the bearing cradle assembly 100.

As can be seen, in the illustrated embodiment, the bearing stud 710 is disposed over a top side A of the first and second top chords 720, 722 and the bearing stud 710 is disposed perpendicularly to the first and second top chords 720, 722. Further, generally, the bearing stud 710 is disposed between the first and second top chords 720, 722 over the top side. The bearing 711 is disposed within the bearing cradle assembly 100.

The top chords may have any physical configuration, such as the illustrated C-shape and, as will be discussed later, are used to mount hat channel brackets on the top chords.

For assembly, the bearing stud 710, with the bearing 711 attached, of the rigid top chord assembly 700 is first positioned in the lower, second half-cylindrical bearing cap member 134 and then the upper, first half-cylindrical bearing cap member 132 is positioned over the bearing stud 710. The bearing stud 710 is then secured in the first and second half-cylindrical bearing cap members 132, 134 of the cylindrical bearing cap 130 by the first mounting member 120 and second mounting member 122. The mounting members 120, 122 may be any structures, such as metal straps. All that is required is that they are able to configure the first and second half-cylindrical bearing cap members 132, 134 of the cylindrical bearing cap 130 together such that the bearing stud 710 is retained in the cylindrical bearing cap 130.

As such, the bearing stud 710 is rotatable within the cylindrical bearing cap 130 of the bearing cradle assembly 100.

As mentioned above, the mounting assembly further includes a plurality of hat channels 800. The hat channels 800 have a “hat-shaped”, or T-shaped, profile and are attached to the first and second top chords 720, 722. The hat channels 800 are disposed on the top side A of the first and second top chords 720, 722, as is the bearing stud 710. The hat channels 800 are disposed perpendicularly to the first and second top chords 720, 722, and parallel to a torsion tube 1000, as will be further discussed later, and extend between (span) adjacent top chord assemblies, and thus, adjacent mounting piles of the mounting assembly.

A photovoltaic module(s) 900 is attached to the hat channels 800.

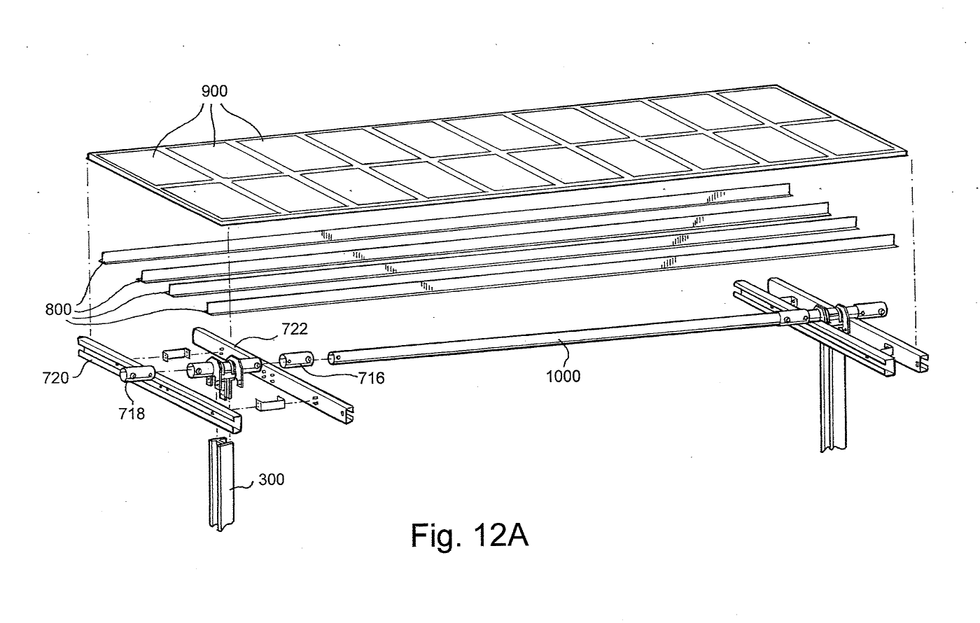

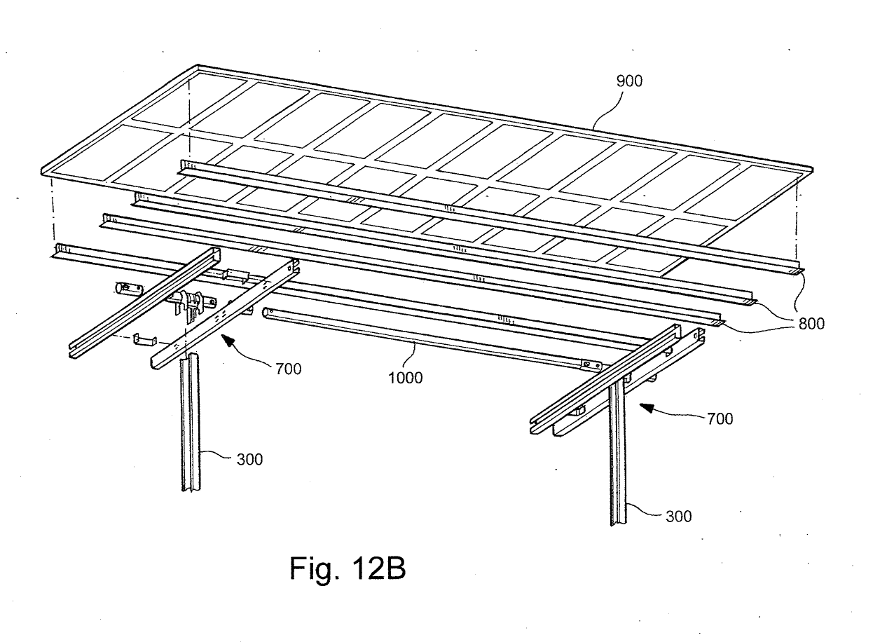

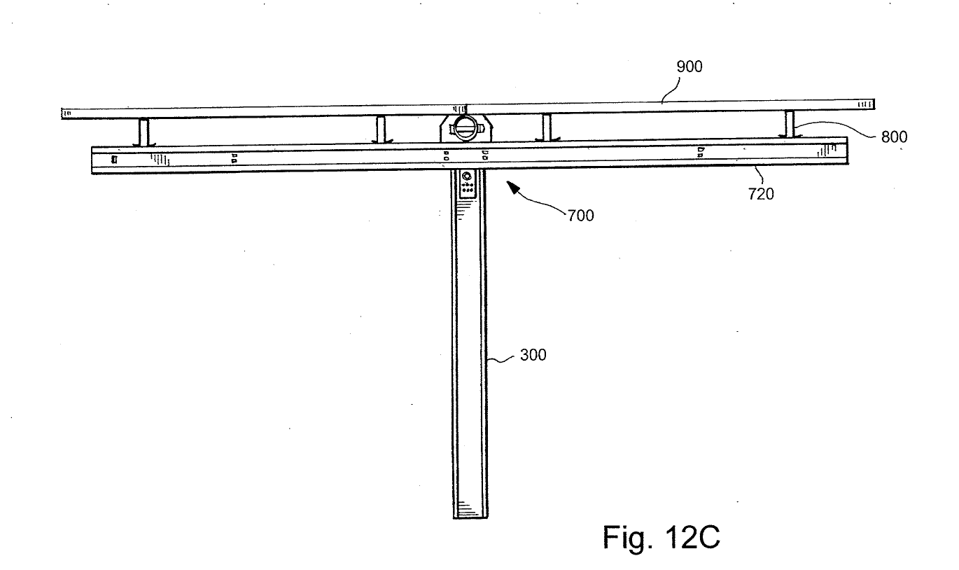

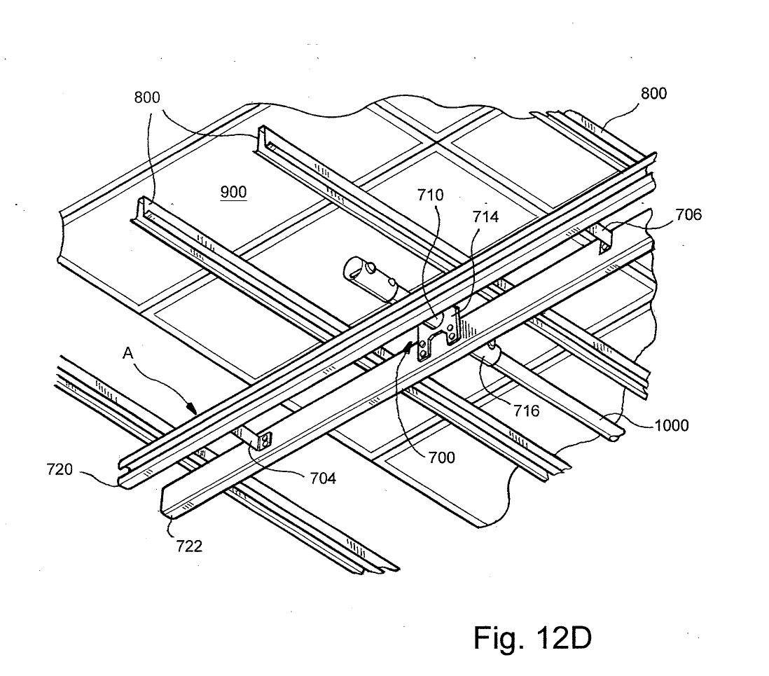

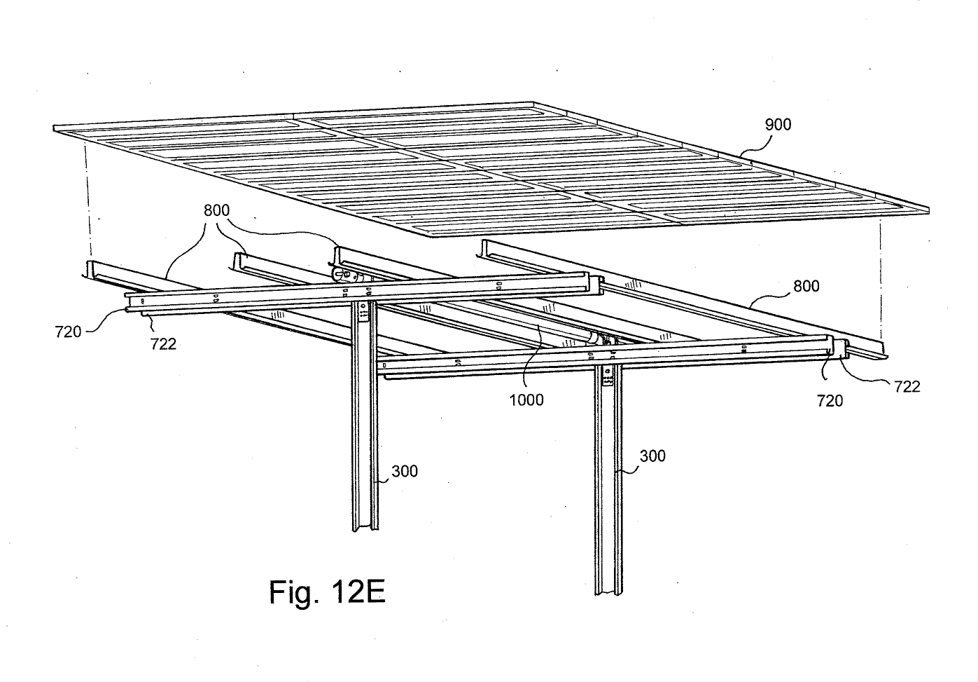

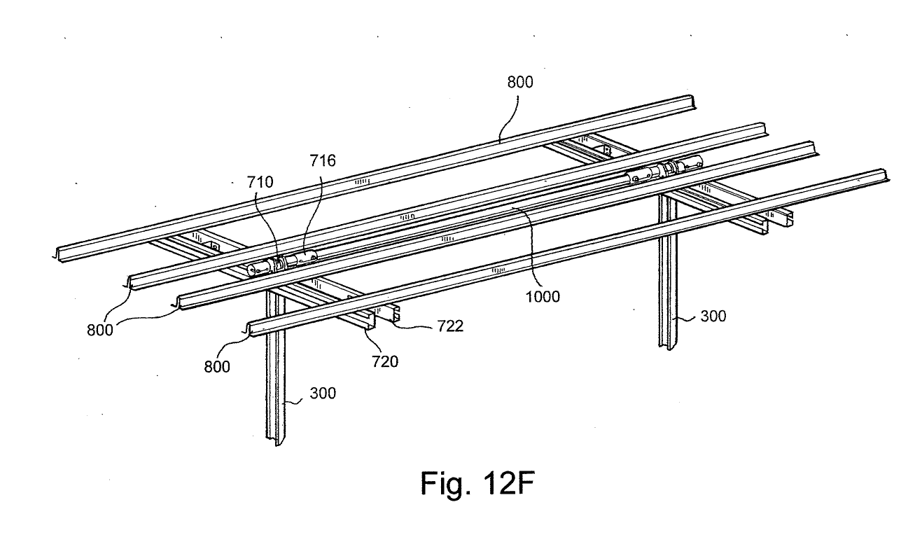

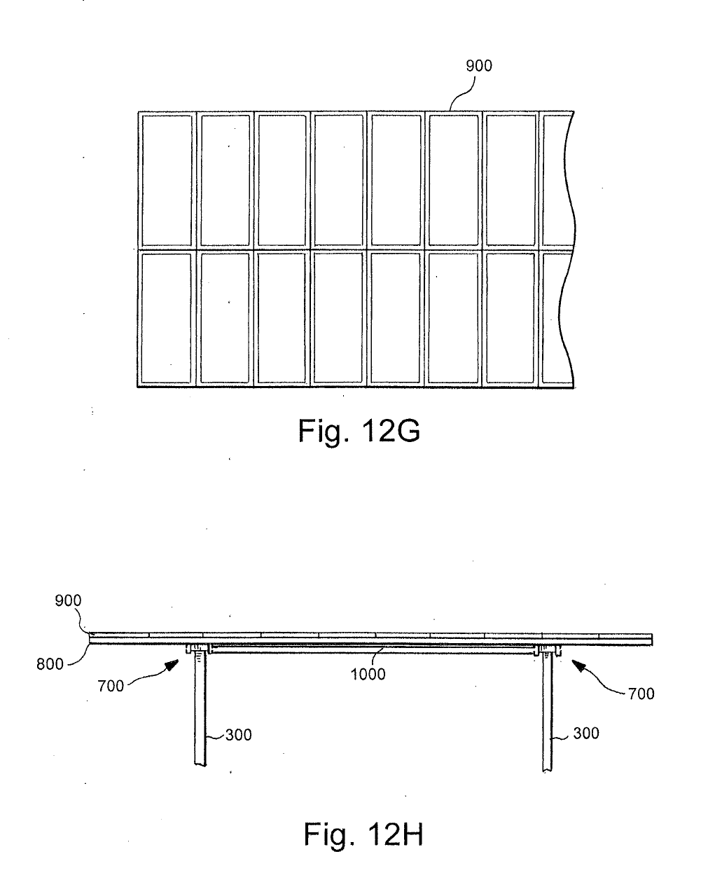

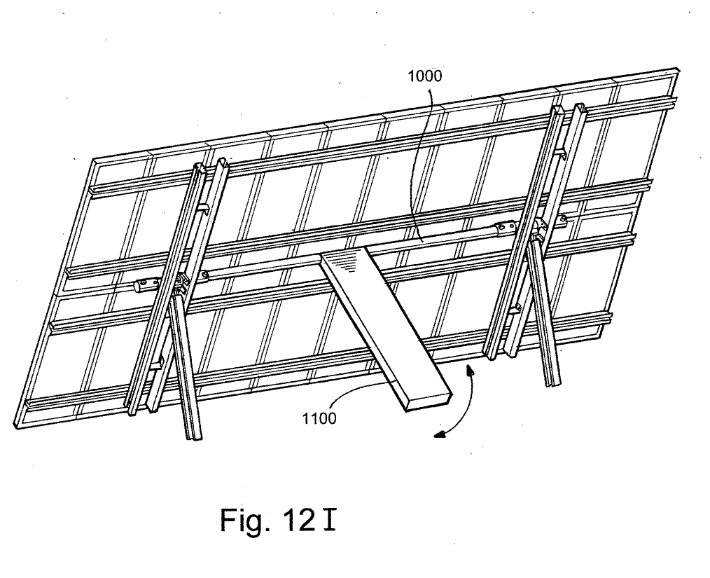

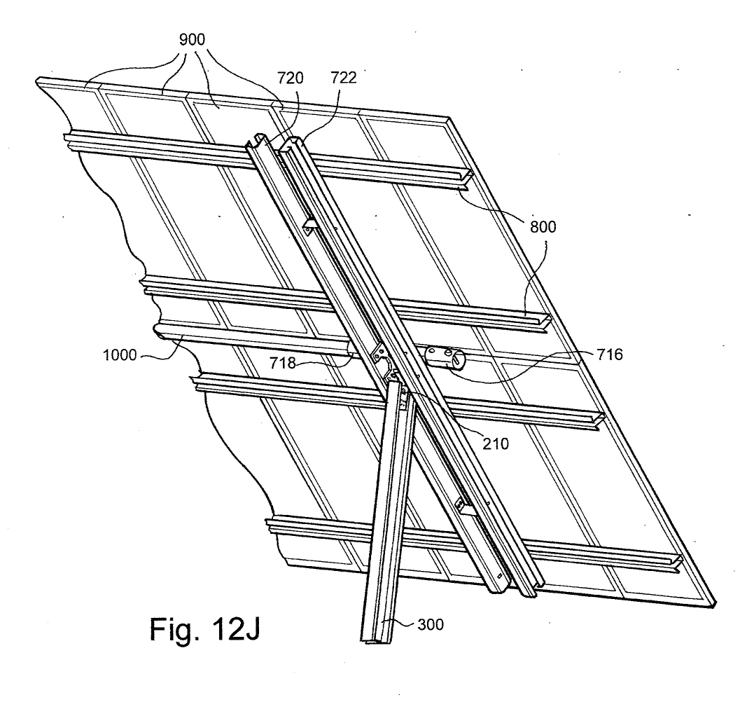

FIGS. 12A-12J illustrate an assembled mounting assembly in accordance with the principles of the present invention.

As can be further seen, a first sleeve 716 is attached to a first end of the bearing stud 710 and a second sleeve 718 may be attached to a second, opposite end of the bearing stud 710. A first torsion tube 1000 is attached to the first sleeve 716 and a second torsion tube may be attached to the second sleeve 718. These torsion tubes extend between adjacent mounting piles 300, and thus between adjacent top chord assemblies, of a photovoltaic panel mounting assembly. Thus, they span the length between adjacent mounting piles and top chord assemblies, and are attached on each of their ends to the respective sleeves of the adjacent top chord assemblies that are associated with each of the adjacent mounting piles.

As can be further seen in FIG. 121, an actor 1100 is attached to torsion tube 1000. As discussed, the system of the present invention is a mounting assembly for mounting a photovoltaic module(s). The system is a tracker that is able to turn the photovoltaic modules such that, for example, they can be positioned in a desirable position with respect to the sun throughout the course of the day. Thus, the modules are able to rotate around an axis defined by the torsion tube. In order to rotate the modules, the torsion tube is rotated and the actor 1100 is used to rotate the torsion tube 1000. The present invention is not limited to any particular structure for the actor. All that is required is that a mechanism is provided in order to move the torsion tube, which in-turn, moves the photovoltaic modules.

In assembling the mounting assembly, generally, the mounting piles 300 are set with respect to the ground. For each pile, the bearing cradle assembly 100 and bracket assembly 200 are attached to each other and connected to the pile by shot pins 400. The top chord assembly 700 is assembled and set into the bearing cradle assembly 100 in forming the bearing assembly 750. The hat channels 800 are attached to adjacent top chord assemblies 700. Torsion tubes 1000 are connected between adjacent top chord assemblies, and thus, between adjacent mounting piles. Photovoltaic modules 900 are attached to the hat channels 800.

Thus, in accordance with the principles of the present invention, the hat channels 800 and top chords 720, 722, and thus the PV modules 900, are not attached to the torsion tube 1000, but rather, are connected to the mounting piles 300 via the bearing assembly 750. As such, the PV modules 900 are not supported between mounting piles 300 by the torsion tubes 1000, but rather, are supported on the mounting piles by the hat channels, top chords, mounting brackets, bearing stud, bearing cradle assembly, and the pile mounting brackets.

Therefore, as can be understood, through the principles of the present invention, generally only torsion loads, e.g., wind-induced torque loads, are applied to the torsion tubes that extend between adjacent mounting piles and top chord assemblies. The span loads are applied to the mounting pile 300 via the connected structures of the hat channels 800, top chord assembly 700, bearing cradle assembly 100, and bracket assembly 200, and via the bearing assembly 750. These span loads are loads that have a component other than a torsion component, and are, for example, due to gravitational forces on the structural components of the assembly, snow accumulated on the assembly, etc. For example, if the PV array was tilted and subject to wind, the hat channels would carry wind loads perpendicular to the modules and the torsion tubes would carry torsional loads from the wind acting on the modules to create a moment around the torsion tubes. As such, with the present invention, the span loads are separated from the torque loads. The span loads are directed into the mounting pile without loading the torsion tubes and the torsion tubes only bear torque loads.

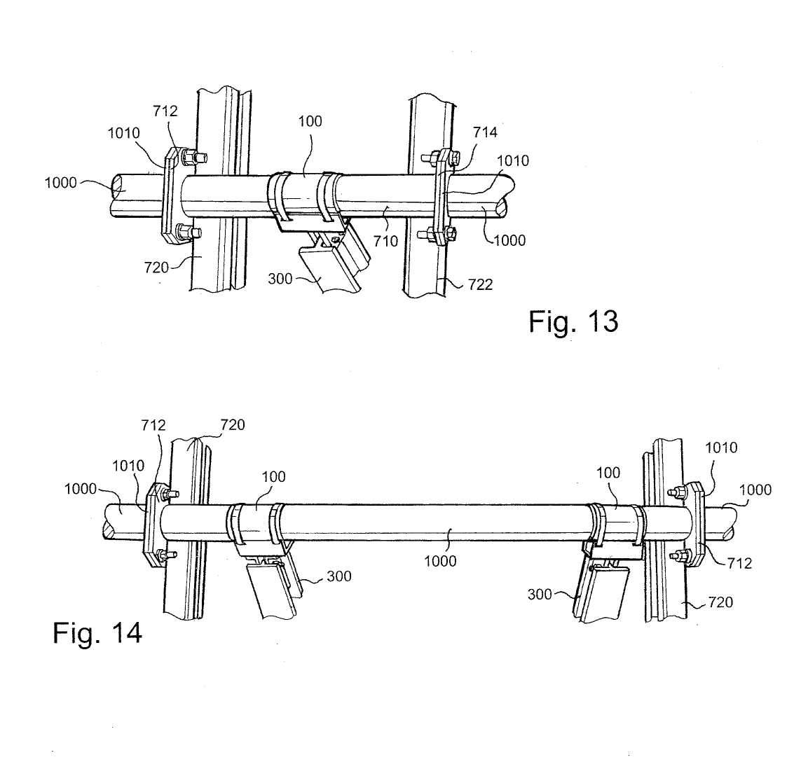

In a further embodiment of a top chord assembly of the present invention, as can be seen in FIG. 13, the first top chord mounting bracket 712 and the second top chord mounting bracket 714 are located at respective distal ends of the bearing stud 710. The first top chord 720 is located on an inside of first top chord mounting bracket 712, i.e., on the side closest to mounting pile 300, and likewise, the second top chord 722 is also located on an inside of second top chord mounting bracket 714, i.e., on the side closest to mounting pile 300.

As can be further seen in the embodiment of FIG. 13, first sleeve 716 and second sleeve 718 of FIGS. 11A and 11B are not utilized. Instead of using sleeves 716, 718 to connect torsion tubes 1000 to bearing stud 710, the torsion tubes 1000 are directly secured to the first top chord mounting bracket 712 and the second top chord mounting bracket 714, e.g., by a two bolt splice. As such, the ends of the torsion tubes 1000 have a plate 1010 formed thereon that correlates to the mounting brackets 712, 714. The bolts secure the plates 1010 to the mounting brackets 712, 714.

In an additional embodiment of a top chord assembly of the present invention, as can be seen in FIGS. 14-16, a bearing stud 710, and sleeves 716, 718, are not utilized. Instead, torsion tube 1000 extends between and beyond two mounting piles 300 and is disposed through the bearing cradle assemblies 100 that are associated with the two mounting piles 300. As such, respective cylindrical bearings 711 are disposed on the torsion tube at the location of the bearing cradle assemblies 100.

In this embodiment, as can be seen, only a single top chord, and thus only a single top chord mounting bracket, is used at each mounting pile 300. Accordingly, at one end of the torsion tube 1000 that extends between the two mounting piles 300, a top chord mounting bracket 712 is provided. Thus, mounting bracket 712 is disposed at an end of the torsion tube, and may be integrally formed with the torsion tube. Top chord 720 is attached to the top chord mounting bracket 712.

Similarly, at the other end of the torsion tube 1000 that extends between the two mounting piles 300, a top chord mounting bracket 712 is also provided. Thus, this mounting bracket 712 is also disposed at an end of the torsion tube, and may also be integrally formed with the torsion tube. Another top chord 720 is attached to this top chord mounting bracket 712 at this end of the torsion tube.

Further with this embodiment, on both ends of the torsion tube 1000 that extends between the two mounting piles 300, an additional torsion tube 1000 may be attached to the top chord mounting bracket 712 on an opposing side of the mounting bracket from the top chord 720. As such, as described above, the end of the additional torsion tube 1000 has a plate 1010 formed thereon that correlates to the mounting bracket 712. Bolts secure the plate 1010 to the mounting bracket 712. These additional torsion tubes on the outside of the mounting brackets, if utilized, extend to an adjacent mounting pile and are attached to the outside of a mounting bracket associated with that adjacent mounting pile.

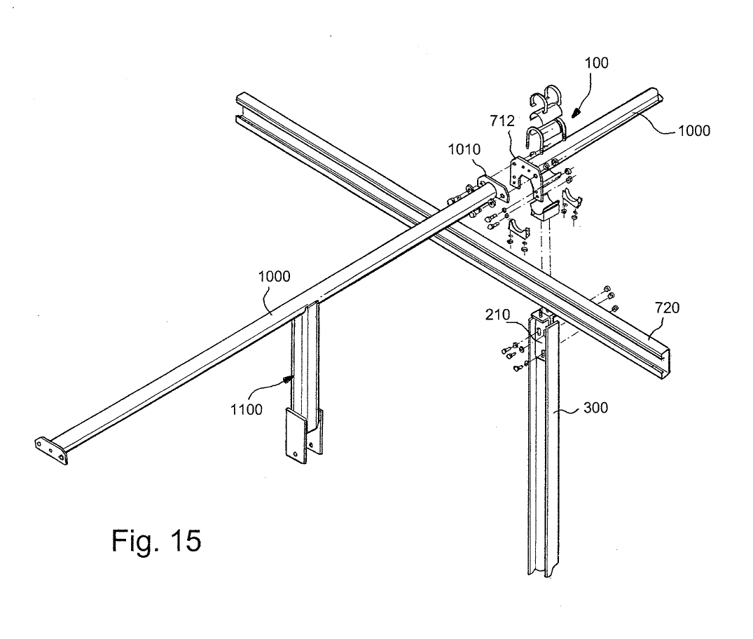

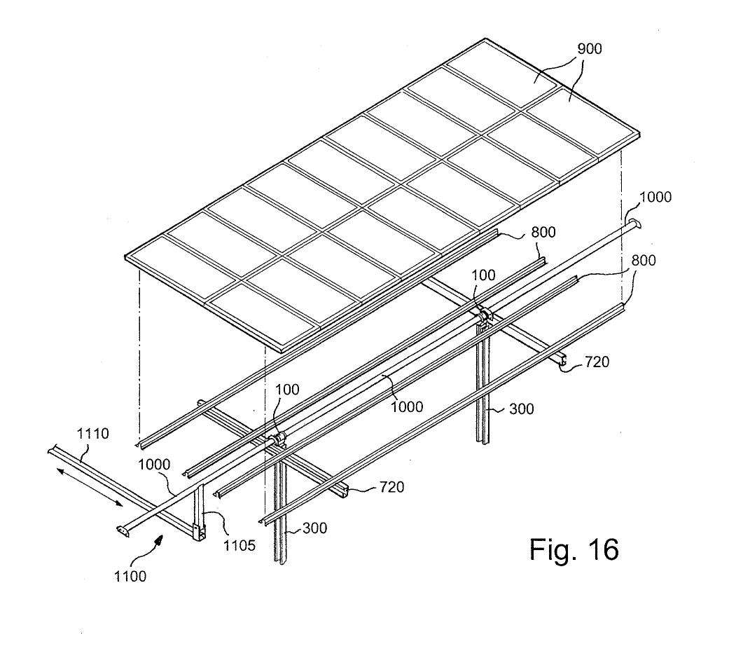

As can be further seen in FIGS. 15 and 16, it is not required that the top chord 720 be located on the inside of the top chord mounting bracket 712. The top chord 720 can be located on the outside of the top chord mounting bracket without departing from the spirit and scope of the present invention.

Further, FIGS. 15 and 16 additionally illustrate an actor 1100 that was described previously. Actor 1100 includes a drive arm 1105 that is attached to torsion tube 1000 and a drive link 1110 that is attached to drive arm 1105.

Lastly with respect to the embodiments of FIGS. 13-16, shot pins are not used to attach the mounting brackets 210, 220 to the mounting pile 300. Rather, bolts are used. With this embodiment, a horizontal slot can be provided in the mounting pile and a vertical slot can be provided in the mounting bracket, which slots align and receive through them a bolt. With this configuration, the aligned slots provide for a construction tolerance. Of course, multiple aligned slots and associated bolts can be provided. With this embodiment, a bolt 230 is not required.

Thus, with the embodiment of FIGS. 14-16, even though a bearing stud is not used, generally only torsion loads, e.g., wind-induced torque loads, are applied to the torsion tubes that extend between adjacent mounting piles. The span loads are applied to the mounting pile 300 since the top chords are supported in close proximity to the mounting pile.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A photovoltaic module mounting assembly, comprising:
a bearing cradle assembly;
a first mounting bracket; and
a second mounting bracket;
wherein the bearing cradle assembly is attached to the first and second mounting brackets.

2. The photovoltaic module mounting assembly according to claim 1, wherein the first and second mounting brackets are L-shaped.

3. The photovoltaic module mounting assembly according to claim 2, wherein an extending portion of the first L-shaped mounting bracket is disposed in an opposite direction from an extending portion of the second L-shaped mounting bracket.

4. The photovoltaic module mounting assembly according to claim 2, wherein an extending portion of the first L-shaped mounting bracket is disposed toward an extending portion of the second L-shaped mounting bracket.

5. The photovoltaic module mounting assembly according to claim 1, wherein the first mounting bracket is connected to the second mounting bracket by a connecting member and wherein the connecting member is a bolt.

6. The photovoltaic module mounting assembly according to claim 5, wherein the first and second mounting brackets are L-shaped and wherein the bolt is disposed through an elongated portion of the first L-shaped mounting bracket and an elongated portion of the second L-shaped mounting bracket.

7. The photovoltaic module mounting assembly according to claim 1, further comprising a mounting pile, wherein the mounting pile is disposed between the first mounting bracket and the second mounting bracket and wherein the mounting pile has a wide flange shape, a square shape, or a round shape.

8. The photovoltaic module mounting assembly according to claim 1, wherein each of the first and second mounting brackets have an indicator and an aperture and wherein the indicator of the first mounting bracket is disposed opposite from the aperture of the second mounting bracket and the aperture of the first mounting bracket is disposed opposite from the indicator of the second mounting bracket.

9. The photovoltaic module mounting assembly according to claim 1, wherein the bearing cradle assembly includes a U-shaped mounting base, a first mounting member and a second mounting member, and a cylindrical bearing cap including a first half-cylindrical bearing cap member and a second half-cylindrical bearing cap member, and wherein the cylindrical bearing cap is secured on the U-shaped mounting base by the first and second mounting members.

10. The photovoltaic module mounting assembly according to claim 9, wherein the U-shaped mounting base includes a first crescent-shaped slot and a second crescent-shaped slot, wherein the first crescent-shaped slot is aligned with a slot in the first mounting bracket, and wherein the second crescent-shaped slot is aligned with a slot in the second mounting bracket.

11. The photovoltaic module mounting assembly according to claim 10, wherein a first bolt extends through the first crescent-shaped slot and the slot in the first mounting bracket and wherein a second bolt extends through the second crescent-shaped slot and the slot in the second mounting bracket.

12. The photovoltaic module mounting assembly according to claim 1, further comprising a mounting pile, wherein the mounting pile is disposed between the first mounting bracket and the second mounting bracket, wherein each of the first and second mounting brackets have an indicator and an aperture, wherein the indicator of the first mounting bracket is disposed opposite from the aperture of the second mounting bracket and the aperture of the first mounting bracket is disposed opposite from the indicator of the second mounting bracket, and wherein a first shot pin is disposed through the indicator of the first mounting bracket, through the mounting pile, and in the aperture of the second mounting bracket, and wherein a second shot pin is disposed through the indicator of the second mounting bracket, through the mounting pile, and in the aperture of the first mounting bracket.

13. The photovoltaic module mounting assembly according to claim 1, further comprising a mounting pile, wherein the mounting pile is disposed between the first mounting bracket and the second mounting bracket, wherein a first shot pin is disposed through the first mounting bracket and the mounting pile, and wherein a second shot pin is disposed through the second mounting bracket and the mounting pile.

14. The photovoltaic module mounting assembly according to claim 1, further comprising a mounting pile and a C-clamp, wherein the mounting pile is disposed between the first mounting bracket and the second mounting bracket, and wherein the C-clamp connects the first and second mounting brackets to the mounting pile.

15. The photovoltaic module mounting assembly according to claim 9, further comprising a bearing stud, wherein the bearing stud is rotatably disposed within the bearing cradle assembly.

16. The photovoltaic module mounting assembly according to claim 15, wherein the bearing stud is connected to a first top chord and a second top chord and wherein the first top chord is adjacent to, and parallel to, the second top chord.

17. The photovoltaic module mounting assembly according to claim 16, wherein the bearing stud is rigidly connected to the first and second top chords by a first top chord mounting bracket and a second top chord mounting bracket, wherein the first top chord mounting bracket is rigidly connected to the bearing stud and the first top chord, and wherein the second top chord mounting bracket is rigidly connected to the bearing stud and the second top chord.

18. The photovoltaic module mounting assembly according to claim 17, wherein the bearing stud is disposed on a top side of the first and second top chords and wherein the bearing stud is disposed perpendicularly to the first and second top chords.

19. The photovoltaic module mounting assembly according to claim 16:
wherein a first end mounting bracket is disposed between the first top chord and the second top chord at a first end of the first and second top chords and wherein the first end mounting bracket connects the first top chord to the second top chord at the first end;
and wherein a second end mounting bracket is disposed between the first top chord and the second top chord at a second end of the first and second top chords and wherein the second end mounting bracket connects the first top chord to the second top chord at the second end.

20. The photovoltaic module mounting assembly according to claim 16, further comprising a first sleeve attached to a first end of the bearing stud and a second sleeve attached to a second end of the bearing stud.

21. The photovoltaic module mounting assembly according to claim 20, further comprising a first torsion tube attached to the first sleeve and a second torsion tube attached to the second sleeve.

22. The photovoltaic module mounting assembly according to claim 16, further comprising a hat channel, wherein the hat channel is attached to the first and second top chords, wherein the hat channel is disposed on a top side of the first and second top chords, and wherein the hat channel is disposed perpendicularly to the first and second top chords.

23. The photovoltaic module mounting assembly according to claim 22, further comprising a photovoltaic module attached to the hat channel.

24. A photovoltaic module assembly, comprising:
a mounting pile;
a bearing assembly connected to the mounting pile;
a top chord connected to the bearing assembly;
a hat channel attached to the top chord;
a photovoltaic module attached to the hat channel; and
a torsion tube connected to the bearing assembly, wherein the torsion tube is not attached to the top chord, the hat channel, and the photovoltaic module.

25. The photovoltaic module assembly according to claim 24, further comprising an actor attached to the torsion tube, wherein the torsion tube is rotatable by the actor.

26. The photovoltaic module assembly according to claim 24, wherein the hat channel is disposed perpendicular to the top chord and parallel to the torsion tube.

27. A photovoltaic module assembly, comprising:
a first mounting pile with a first bearing cradle assembly connected to the first mounting pile;
a second mounting pile with a second bearing cradle assembly connected to the second mounting pile;
a torsion tube disposed through the first bearing cradle and the second bearing cradle;
a first top chord mounting bracket disposed at a first end of the torsion tube;
a second top chord mounting bracket disposed at a second end of the torsion tube;
a first top chord connected to the first top chord mounting bracket;
a second top chord connected to the second top chord mounting bracket;
a hat channel attached to the first and second top chords; and
a photovoltaic module attached to the hat channel.

28. The photovoltaic module assembly according to claim 27:
wherein the first top chord mounting bracket is integrally formed with the first end of the torsion tube; and
wherein the second top chord mounting bracket is integrally formed with the second end of the torsion tube.
